(19) United States
(12) Patent Application Publication
(10) Pub. No.: US 2011/0002090 A1
(43) Pub. Date: Jan. 6, 2011

(54) Image Display Assembly and Apparatus and Method for Manufacturing the Same

(76) Inventors: Roland Tobias Alfredsson, Gothenburg (SE); Alf Martin Book, Torslanda (SE)

Correspondence Address: QUARLES & BRADY LLP, 411 E. WISCONSIN AVENUE, SUITE 2040, MILWAUKEE, WI, 53202-4497, US

(21) Appl. No.: 12/497,207

(22) Filed: Jul. 2, 2009

(51) Int. Cl. H05K 5/00; H01J 9/38; H01J 9/20

(52) U.S. Cl. 361/679.01; 445/73; 445/24

(57) ABSTRACT

An image display assembly comprising a top glass panel having peripheral edges is disclosed. The image display assembly further comprises an optical film engaged with the top glass panel and having peripheral edges. At least a first of the peripheral edges of the optical film can be disposed inwardly from an adjacent peripheral edge of the top glass panel. The image display further comprises an image display panel engaged with the optical film opposite the top glass panel and having peripheral edges. A peripheral edge of the image display panel adjacent the first peripheral edge of the optical film can be disposed outwardly from the first peripheral edge of the optical film to define an undercut between said optical film and said top glass panel and between said optical film and said image display panel. An apparatus and method for applying the optical film are also disclosed.

### CROSS-REFERENCE TO RELATED APPLICATION

Not applicable.

### STATEMENT REGARDING FEDERALLY SPONSORED RESEARCH OR DEVELOPMENT

Not applicable.

### FIELD OF THE INVENTION

The present invention relates to image display assemblies and particularly protective films and panels for liquid crystal display assemblies.

### BACKGROUND OF THE INVENTION

Image display panels such as liquid crystal display (LCD) devices, organic electroluminescence devices (OELDs), plasma display panel (PDP) devices, and the like are well-known devices commonly used in many flat-panel electronic devices, such as portable media players, cellular phones, computer monitors, televisions, and the like. The thin structure of these electronic devices permitted by the relatively thin image display panels provides more aesthetic appeal than larger conventional displays, such as picture-tube televisions. However, thin image display panels are typically more fragile than conventional displays. As such, contact with other objects during assembly and during use by a consumer can easily damage a thin image display panel.

To address this drawback, most previous image display panels are assembled with protective glass panels, transparent optical film layers, or a combination of both. Unfortunately, these components create additional drawbacks for image display assemblies and manufacturing methods. For example, the structure of image display assemblies sometimes traps gas bubbles between the image display panel, the film layers, and the glass panels. For this reason, manufacturing is conducted, for the most part, within a large vacuum enclosure requiring a substantial amount of power to maintain. These high power requirements increase the cost of image display assemblies. Further still, these large vacuum enclosures include integral flexible gloves so technicians may reach into the enclosure and manually assemble image display assemblies therein. These tasks are highly repetitive and technician fatigue can result in poorly created assemblies in which components are not properly positioned relative to one another. Such assemblies typically require subsequent reworking.

Considering the limitations of previous designs, it would be desirable to have an improved image display assembly and improved assembly devices and methods for manufacturing image display assemblies.

### SUMMARY OF THE INVENTION

In one aspect, the present invention provides an image display assembly comprising a top glass panel having peripheral edges. The image display assembly further comprises an optical film engaged with the top glass panel and having peripheral edges. At least a first of the peripheral edges of the optical film is disposed inwardly from an adjacent peripheral edge of the top glass panel. The image display further comprises an image display panel engaged with the optical film opposite the top glass panel and having peripheral edges. A peripheral edge of the image display panel adjacent the first peripheral edge of the optical film is disposed outwardly from the first peripheral edge of the optical film to define an undercut between said optical film and said top glass panel and between said optical film and said image display panel.

In another aspect of the invention, an apparatus for applying an optical film comprises a support surface and a vacuum head having an open end that is sealable against the support surface. The vacuum head is movable between an open position spaced above the support surface and a sealed position sealingly engaging the support surface. The apparatus further comprises a gripper movably mounted in the vacuum head.

In yet another aspect of the invention, a method of applying an optical film comprises positioning the optical film and one of a top glass panel and an image display panel supported by a first gripper hand of a first gripper assembly within a first vacuum head of the first gripper assembly; forming a seal at an open end of the first vacuum head; removing air from within the first vacuum head to provide a first vacuum chamber therein, the optical film and the one of a top glass panel and an image display panel being disposed in the first vacuum chamber; engaging the optical film with the one of a top glass panel and an image display panel by pressing the one of a top glass panel and an image display panel against the optical film within the first vacuum chamber and using the first gripper hand; and removing a liner releasably supporting the optical film.

The foregoing and advantages of the invention will appear from the following description. In the description, reference is made to the accompanying drawings which form a part hereof, and in which there is shown by way of illustration preferred embodiments of the invention. Such embodiments do not necessarily represent the full scope of the invention, however, and reference is made therefore to the claims herein for interpreting the scope of the invention.

### BRIEF DESCRIPTION OF THE DRAWINGS

The invention will hereafter be described with reference to the accompanying drawings, wherein like reference numerals denote like elements, and:

FIG. 1 is a top view of an image display assembly incorporating the present invention;

FIG. 2 is a side view of the image display assembly of FIG. 1 enlarged in the thickness direction for clarity;

FIG. 3 is a perspective view of an apparatus also incorporating the present invention and for manufacturing the image display assembly;

FIG. 4 is a top view of the apparatus of FIG. 3;

FIG. 5 is a partial side view of a first manufacturing position of the apparatus of FIG. 3;

FIG. 6 is a perspective view of a roll of optical film used for manufacturing the image display assembly;

FIG. 7 is a partial side view of a second manufacturing position of the apparatus of FIG. 3;

FIGS. 8A and 8B are a flowchart of a method also incorporating the present invention and for manufacturing the image display assembly;

FIG. 9 is a top view of an alternative apparatus also incorporating the present invention and for manufacturing the image display assembly; and

FIGS. 10A and 10B are a flowchart of an alternative method also incorporating the present invention and for manufacturing the image display assembly.

### DETAILED DESCRIPTION OF THE PREFERRED EMBODIMENT

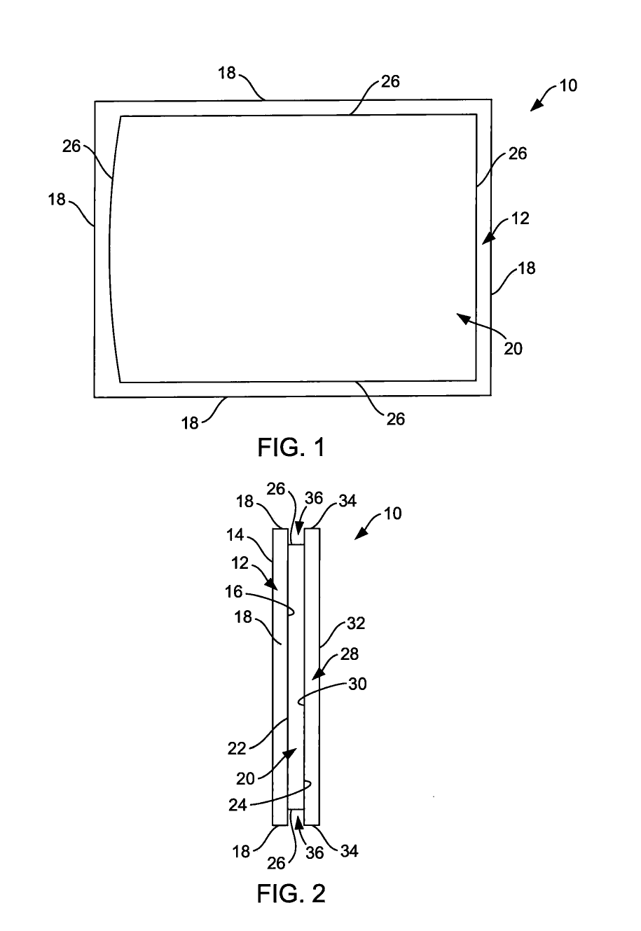

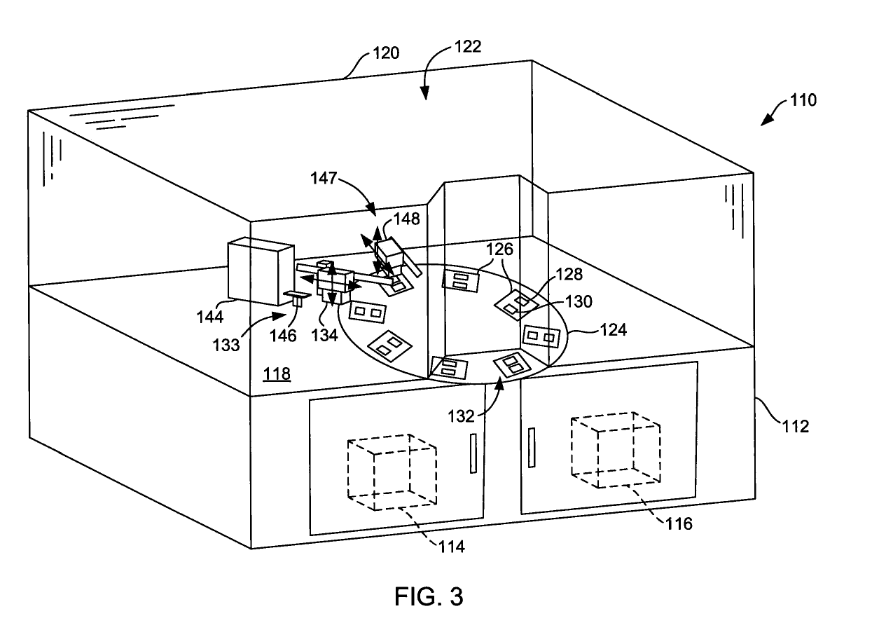

Referring to FIGS. 1-2, an image display assembly 10 incorporating the present invention is a generally rectangular and relatively flat component for use in various types of electronic devices, such as portable media players, cellular phones, flat panel computer screens, and the like. The image display assembly 10 includes a top glass panel 12, such as an acrylic (PMMA) panel, a glass panel, or the like, having a first free end surface 14 and a second end surface 16 connected by peripheral edges 18. It should also be understood that appropriate top glass panels may include substrate layers (not shown) for decorative or protective purposes.

The second end surface 16 of the top glass panel 12 engages an optical film 20, which should be understood as a film comprising one or more thin structured layers of material having advantageous reflective and assembly properties for use in protecting the image display assembly 10. Appropriate optical films 20 include those disclosed the US patent application identified by docket number 180825.00118, the disclosure of which is hereby incorporated by reference in its entirety, filed concurrently with the present application. The optical film 20 includes a first end surface 22 engaged against the top glass panel 12 and a second end surface 24 connected to the first end surface 22 by peripheral edges 26. One or more of the peripheral edges 26 may have an arcuate shape as shown in FIG. 1.

The second end surface 24 of the optical film 20 engages an image display panel 28, which should be understood as any flat panel arrangement of elements capable of displaying static and dynamic images. It should also be understood that appropriate image display panels include substrate layers (not shown) for sealing the functional elements of the display therein. Appropriate image display panels include liquid crystal display (LCD) devices, organic electroluminescence devices (OELDs), plasma display panel (PDP) devices, and the like. The image display panel 28 includes a first end surface 30 engaged against the optical film 20 on which images are displayed. The image display panel 28 also includes a second end surface 32 connected to the first end surface 30 by peripheral edges 34.

The peripheral edges 18, 34 of the top glass panel 12 and the image display panel 28 define respective perimeters that are greater in length than that of the optical film 20. That is, the peripheral edges 26 of the optical film 20 are disposed inwardly (i.e., towards the center of the image display assembly 10) relative to the peripheral edges 18, 34 of the top glass panel 12 and/or the image display panel 28 to essentially provide an “undercut” 36 between the optical film 20 and the top glass panel 12 and between the optical film 20 and the image display panel 28. The undercut 36 advantageously eliminates gas bubbles near the peripheral edges 18, 26, and 34 of the image display assembly 10, thereby providing an improved design. In some embodiments, the undercut 36 may not be needed adjacent each of the peripheral edges 26. As such, the undercut 36 may be disposed about three or fewer of the peripheral edges 26 without departing from the scope of the invention.

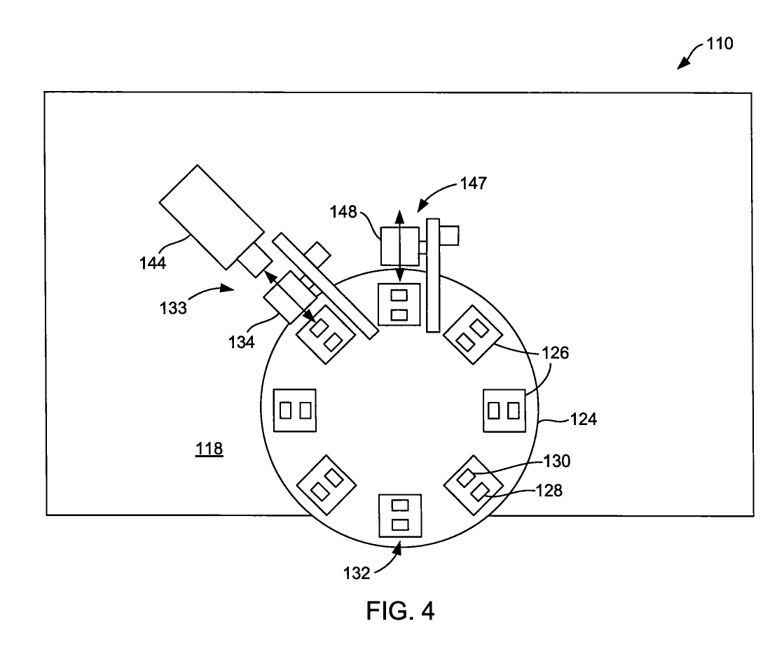

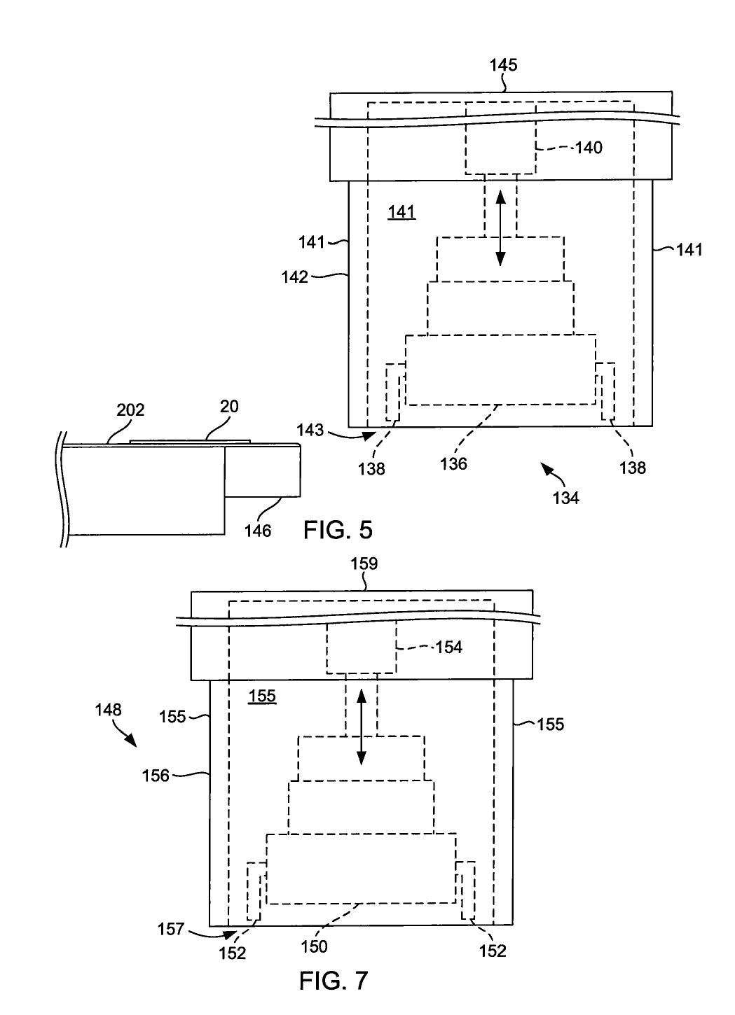

Referring now to FIGS. 3-7, an apparatus 110 also incorporating the present invention and for manufacturing image display assemblies 10 as described above includes a frame 112 supporting electronics 114, such as programmable logic controllers and robotic vision support devices, that control some of the components described below. The frame 112 also houses pneumatics 116, such as vacuum pumps, pressure regulators, and the like, in fluid communication with some of the components described below.

The apparatus 110 also includes a work surface 118 mounted above the frame 112. The work surface 118 supports an enclosure 120 that isolates the outside environment from a work space 122 in which image display assemblies 10 are manufactured to protect the assemblies 10 from contamination. The work surface 118 includes a rotatable index table 124 that may be driven, for example, by an electric motor or the like. The index table 124 mounts a plurality of support fixtures 126; although the figures show eight support fixtures 126, other numbers of support fixtures 126 may be used without departing from the scope of the invention.

Each support fixture 126 includes a first holder 128 and a second holder 130 for supporting components of the image display assembly 10 as described in further detail below. Each support fixture 126 also moves to different manufacturing positions as the index table 124 rotates. For example, the index table 124 rotates to a loading position 132 outside of the enclosure 120 in which components of the image display assembly 10 are loaded and image display assemblies 10 are unloaded from the apparatus 110.

The index table 124 also rotates to a first manufacturing position 133 in which a translatable first gripper assembly 134 manipulates components of the image display assembly 10. The first gripper assembly 134 is moved horizontally by a first drive unit (not shown), such as a linear actuator, a rack and pinion assembly, or the like. Similarly, the first gripper assembly 134 is moved vertically by a second drive unit (not shown), such as a linear actuator, a rack and pinion assembly, or the like.

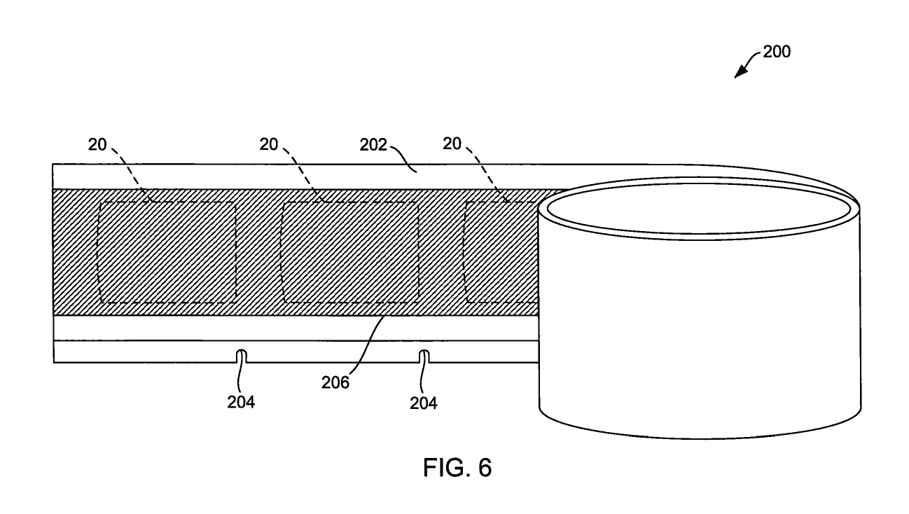

Referring specifically to FIG. 5, the first gripper assembly 134 includes a vacuum head 142 having side walls 141 and a ceiling 145 that are sealed except for an inlet (not shown) for fluid communication with the pneumatics 116 through one or more hoses (not shown). The vacuum head 142 also has an open bottom end 143 that is sealable against a surface, such as the work surface 118, a support fixture 126, or a liner 202. The bottom end 143 may include a gasket (not shown) to further facilitate the seal between the surface and the vacuum head 142. After moving downward to seal against a surface, the vacuum pump (not shown) forming part of the pneumatics 116 draws air from a space defined by the side walls 141, the ceiling 145, and the surface to provide a small vacuum chamber (e.g., 50-500 Pa abs. and preferably less than 400 Pa abs.) therein.

The first gripper assembly 134 further includes a gripper hand 136 having fingers 138 that support components of the image display assembly 10. The gripper hand 136 and fingers 138 connect to a linear actuator 140, such as a pneumatic actuator in fluid communication with the pneumatics 116, and thereby translate vertically relative to the vacuum head 142 after the vacuum head 142 forms a seal against another object and the vacuum chamber is provided. As such, the gripper hand 136 presses components of the image display assembly 10 together within the vacuum chamber.

An optical film dispenser 144 is also disposed at the first manufacturing position 133. In general, the optical film dispenser 144 may be any appropriate design known in the art. In addition, the optical film dispenser 144 includes a translatable dispensing platform 146 that is driven by a linear actuator, a rack and pinion assembly, or the like. The dispensing platform 146 presents optical film 20 to the first gripper assembly 134.

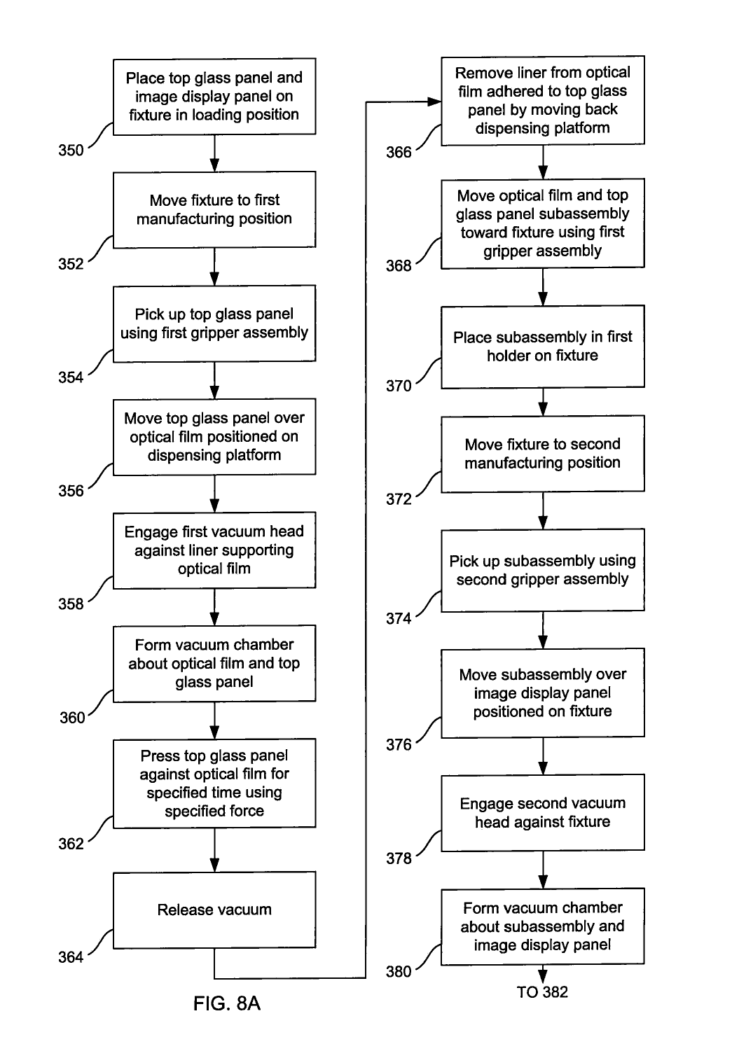

Referring specifically to FIG. 6, the optical film dispenser 144 preferably dispenses optical film 20 on a roll 200 including a liner 202 that supports a series of die cut optical film segments 20. The liner 202 preferably includes indexing notches 204 that are sensed by the optical film dispenser 144 so that the optical film segments 20 may be properly positioned on the dispensing platform 146. The roll 200 also preferably includes an upper protective liner 206 that is removed by the optical film dispenser 144 before presenting optical film 20 to the first gripper assembly 134.

Referring again to FIGS. 3-7, the index table 124 also rotates to a second manufacturing position 147 in which a translatable second gripper assembly 148 manipulates components of the image display assembly 10. The second gripper assembly 148 is moved horizontally by a third drive unit (not shown), such as a linear actuator, a rack and pinion assembly, or the like. Similarly, the second gripper assembly 148 is moved vertically by a fourth drive unit (not shown), such as a linear actuator, a rack and pinion assembly, or the like.

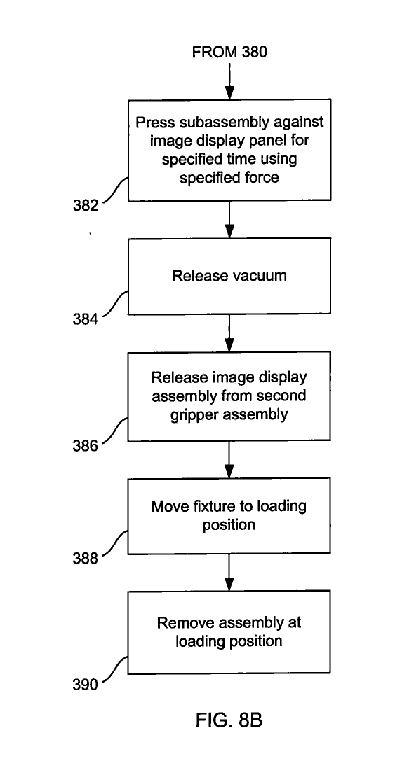

Referring specifically to FIG. 7, the second gripper assembly 148 includes a vacuum head 156 having side walls 155 and a ceiling 159 that are sealed except for an inlet (not shown) for fluid communication with the pneumatics 116 through one or more hoses (not shown). The vacuum head 156 also has an open bottom end 157 that is sealable against a surface, such as the work surface 118, a support fixture 126, or the liner 202. After moving downward to seal against the surface, the vacuum pump (not shown) forming part of the pneumatics 116 draws air from a space defined by the side walls 155, the ceiling 159, and the surface to provide a small vacuum chamber (e.g., 50-500 Pa abs. and preferably less than 400 Pa abs.) therein.

The second gripper assembly 148 further includes a gripper hand 150 having fingers 152 that support components of the image display assembly 10. The gripper hand 150 and fingers 152 connect to a linear actuator 154, such as a pneumatic actuator in fluid communication with the pneumatics 116, and thereby translate vertically relative to the vacuum head 156 after the vacuum head 156 forms a seal against another object and the vacuum chamber is provided. As such, the gripper hand 150 presses components of the image display assembly 10 together within the vacuum chamber.

As described briefly above, the apparatus 110 may include robotic vision devices (not shown) in communication with electronics 114 for guiding the first and second gripper assemblies 134 and 148. Such robotic vision devices may be any appropriate designs that permit image display assemblies 10 to be manufactured with relatively high precision.

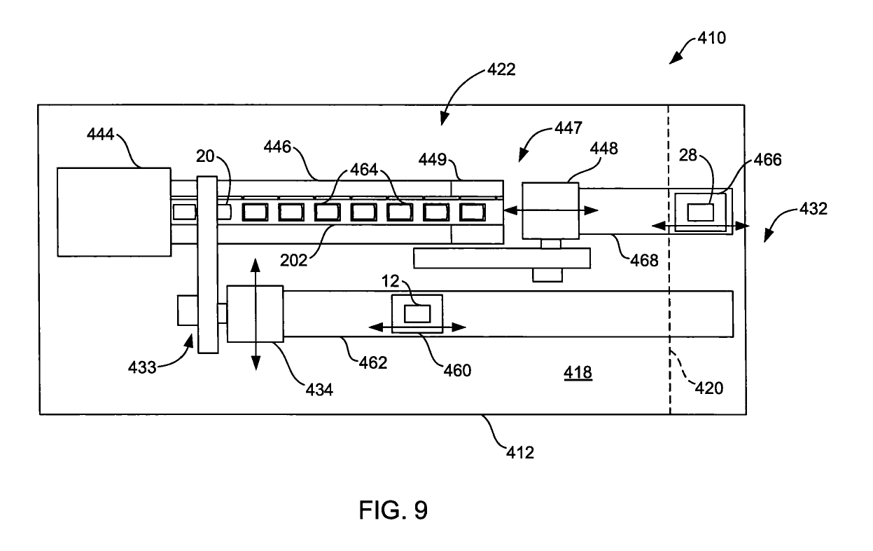

Referring now to FIGS. 8A and 8B, in one embodiment, the apparatus 110 assembles an image display assembly 10 as described below. A single top glass panel 12 and a single image display panel 28 are loaded in the first and second holders 128 and 130, respectively, of a support fixture 126 in the loading position 132 in step 350. The index table 124 rotates the fixture 126 into the enclosure 120 to the first manufacturing position 133 in step 352. The first gripper assembly 134 engages and picks up the top glass panel 12 in step 354. The first gripper assembly 134 moves the top glass panel 12 over an optical film segment 20 positioned on the dispensing platform 146 of the optical film dispenser 144 in step 356.

The bottom end 143 of the vacuum head 142 sealingly engages the liner 202 surrounding the optical film segment 20 on the dispensing platform 146 and the fingers 138 of the first gripper assembly 134 simultaneously hold the top glass panel 12 above the optical film segment 20 on the dispensing platform 146 in step 358. The vacuum pump forming part of the pneumatics 116 draws air from the vacuum head 142 to form a vacuum chamber about the optical film segment 20 and the top glass panel 12 in step 360. When a sufficient vacuum is provided within the vacuum head 142, the gripper hand 136 moves downwardly to press the top glass panel 12 against the optical film segment 20 for an appropriate time using an appropriate force considering the specific materials of the glass panel 12 and the optical film segment 20 in step 362. The vacuum is then released in step 364 and the liner 202 is removed from the optical film segment 20 by moving the dispensing platform 146 holding the liner 202 away from the first gripper assembly 134 in step 366. This provides a subassembly comprising the optical film segment 20 adhered to the top glass panel 12.

The first gripper assembly 134 moves the subassembly toward the fixture 126 in step 368 and places the subassembly in the first holder 128 on the fixture 126 in step 370. The index table 124 then rotates the fixture 126 to the second manufacturing position 147 in step 372. The second gripper assembly 148 engages and picks up the subassembly in step 374. The second gripper assembly 148 moves the subassembly over the image display panel 28 positioned in the second holder 130 of the fixture 126 in step 376. The bottom end 157 of the vacuum head 156 sealingly engages the surface of the fixture 126 around the image display panel 28 and the fingers 152 of the second gripper assembly 148 simultaneously hold the subassembly above the image display panel 28 in step 378. The vacuum pump forming part of the pneumatics 116 draw air from the vacuum head 156 to form a vacuum chamber about the subassembly and the image display panel 28 in step 380. When a sufficient vacuum is provided within the vacuum head 156, the gripper hand 150 presses the subassembly against the image display panel 28 for an appropriate time using an appropriate force to connect the optical film 20 to the image display panel 28 in step 382. Such appropriate time and force values may be determined considering the specific materials of the glass panel 12, the optical film segment 20, and the image display panel 28. The vacuum chamber is then released in step 384 and the second gripper assembly 148 releases the image display assembly 10 in step 386, thereby leaving the assembly 10 in the second holder 130 of the fixture 126. The index table 124 rotates the fixture 126 to the loading position 132 in step 388 and the assembly 10 is removed from the fixture 126 in step 390.

It should be noted that several steps of the method described above can be performed simultaneously with different sets of components. For example, the following actions may be performed simultaneously: a first set of components may be loaded into a first fixture, the first gripper assembly and the optical film dispenser may interact with a second set of components, and the second gripper assembly may interact with a third set of components. Further still, it should be noted that the order of connecting the top glass panel and the image display panel to the optical film may be reversed without departing from the scope of the invention.

The apparatus and method for manufacturing image display assemblies 10 may vary from those described above without departing from the scope of the invention. For example, the apparatus 110 can be modified so that image display assemblies 10 are manufactured in a single gripper assembly. However, such an apparatus may lead to increased cycle time because fewer steps described above may be performed simultaneously. As another example, the gripper assemblies and fixtures may be positioned in different orientations (e.g., facing horizontally, upside-down, and the like) than those described above, and the optical film 20 may be connected to the top glass panel 12 proximate a fixture 126 instead of the optical film dispenser 144.

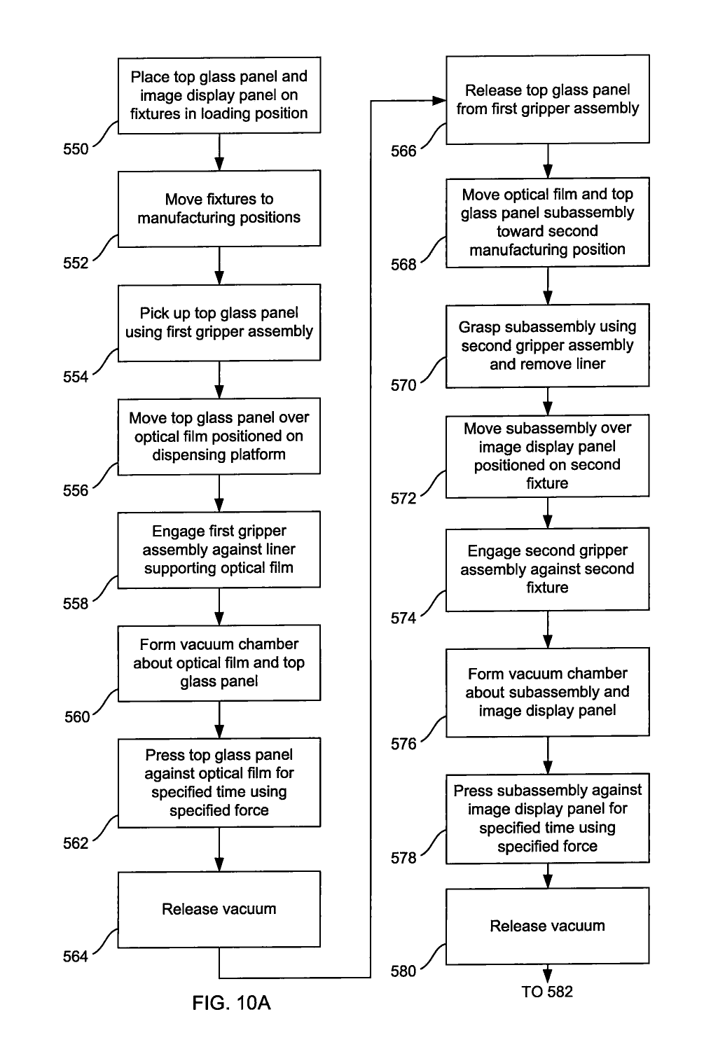

As yet another example and referring now to FIG. 9, an alternative apparatus 410 for manufacturing image display assemblies 10 includes a frame 412 supporting electronics (not shown) and pneumatics (not shown) as described above. The frame 412 supports an enclosure, one side of which is shown as reference numeral 420. The enclosure isolates the outside environment from a work space 422 in which image display assemblies 10 are manufactured to protect the assemblies 10 from contamination as described above.

The frame 412 also mounts a work surface 418 that supports a first translatable fixture 460. The first translatable fixture 460 is driven by a drive unit (not shown), such as a linear actuator, a chain and sprocket assembly or the like, and guided within a first track or set of rails 462. The drive unit moves the first translatable fixture 460 to a loading position 432 outside of the enclosure in which top glass panels 12 are loaded into the first translatable fixture 460. The drive unit also moves the first translatable fixture 460 to a first manufacturing position 433 to provide top glass panels 12 to a first gripper assembly 434. The first gripper assembly 434 is as described above.

The fingers (not shown) of the first gripper assembly 434 lift the top glass panel 12 from the first translatable fixture 460. The first gripper assembly 434 also moves to a position above a dispensing platform 446 of an optical film dispenser 444 on which a liner 202 supporting a series of optical film segments 20 is positioned. As described above, an open bottom end (not shown) of the first gripper assembly 434 seals against the liner 202 so that a vacuum chamber may be provided within the first gripper assembly 434 for assembly of the top glass panel 12 and the optical film 20.

Unlike the first embodiment of the apparatus 110, the liner 202 is not removed from the optical film 20 after the first gripper assembly 434 connects the top glass panel 12 to the optical film 20. Instead, the liner 202 transports optical film/top glass panel subassemblies 464 to a second manufacturing position 447. The second manufacturing position 447 may include a movable dispensing surface 449 that presents optical film/top glass panel subassemblies 464 to a second gripper assembly 448. The second gripper assembly 448 is as described above. The fingers (not shown) of the second gripper assembly 448 grasp and remove optical film/top glass panel subassemblies 464 from the liner 202 by permitting the dispensing surface 449 to move backwards and away from the second gripper assembly 448. The second gripper assembly 448 also moves to a position above a second translatable fixture 466 that supports image display panels 28. As described above, an open bottom end (not shown) of the second gripper assembly 448 seals against the second translatable fixture 466 so that a vacuum chamber may be provided within the second gripper assembly 448 for assembly of the image display panel 28 and the subassembly 464.

The second translatable fixture 466 is driven by a drive unit (not shown), such as a linear actuator, a chain and sprocket assembly or the like, and guided within a second track or set of rails 468. The drive unit moves the second translatable fixture 466 from the second manufacturing position 447 to the loading position 432 outside of the enclosure. Completed image display assemblies 10 are removed from the second translatable fixture 466 and image display panels 28 are placed on the second translatable fixture 466 in the loading position 432.

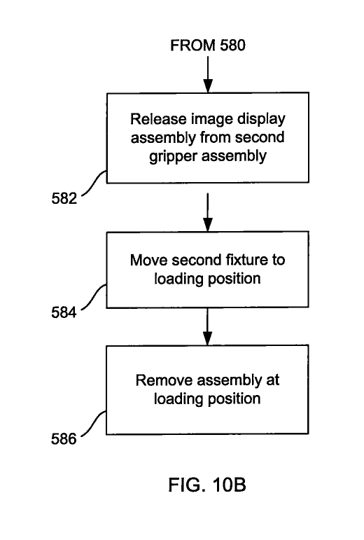

Referring now to FIGS. 10A and 10B, in one embodiment, the apparatus 410 manufactures an image display assembly 10 as described below. A single top glass panel 12 and a single image display panel 28 are loaded on the first and second fixtures 460 and 466, respectively, in the loading position 432 in step 550. The first fixture 460 moves into the enclosure to the first manufacturing position 433 and the second fixture 466 moves into the enclosure to the second manufacturing position 447 in step 552. The first gripper assembly 434 engages and picks up the top glass panel 12 in step 554. The first gripper assembly 434 moves the top glass panel 12 over an optical film segment 20 positioned on the dispensing platform 446 of the optical film dispenser 444 in step 556.

The first gripper assembly 434 sealingly engages the liner 202 surrounding the optical film segment 20 on the dispensing platform 446 as described above in step 558. The fingers of the first gripper assembly 434 simultaneously hold the top glass panel 12 above the optical film segment 20 on the dispensing platform 146. A vacuum pump forming part of the pneumatics draws air from the first gripper assembly 434 as described above to form a vacuum chamber about the optical film segment 20 and the top glass panel 12 in step 560. When a sufficient vacuum is provided, the gripper fingers move downwardly to press the top glass panel 12 against the optical film segment 20 for an appropriate time using an appropriate force in step 562. The vacuum is then released in step 564 and the first gripper assembly 434 releases the top glass panel 12 in step 566. This provides a subassembly 464 comprising the optical film segment 20 adhered to the top glass panel 12 and supported by the liner 202.

The liner 202 moves the subassembly 464 toward the second manufacturing position 447 and the dispensing surface 449 in step 568. The second gripper assembly 448 grasps the subassembly 464 and the dispensing surface 449 removes the liner 202 from the subassembly 464 by moving backwards in step 570. The second gripper assembly 448 moves the subassembly 464 over the image display panel 28 positioned in the second fixture 466 in step 572.

The second gripper assembly 448 sealingly engages the surface of the second fixture 466 around the image display panel 28 as described above in step 574. The fingers of the second gripper assembly 448 simultaneously hold the subassembly above the image display panel 28. The vacuum pump forming part of the pneumatics draw air from the second gripper assembly 448 as described above to form a vacuum chamber about the subassembly 464 and the image display panel 28 in step 576. When a sufficient vacuum is provided, the gripper fingers press the subassembly 464 against the image display panel 28 for an appropriate time using an appropriate force to connect the optical film 20 to the image display panel 28 in step 578. The vacuum chamber is then released in step 580 and the second gripper assembly 448 releases the image display assembly 10 in step 582, thereby leaving the assembly 10 in the second fixture 466. The second fixture 466 moves the image display assembly 10 to the loading position 432 in step 584 and the assembly 10 is removed from the second fixture 466 in step 586.

The apparatus and method described above advantageously provide increased precision when manufacturing image display assemblies 10. For example, most of the dispensing platform 446 is stationary, and therefore a more stable surface is provided for precisely connecting top glass panels 12 and optical film segments 20. As another example, only a single fixture 466 is provided for connecting subassemblies 464 and image display panels 28. As such, these components can be more precisely connected compared to an apparatus that includes multiple fixtures having slightly different dimensions than one another.

Of course, several steps of the method described above can be performed simultaneously with different sets of components. For example, the following actions may be performed simultaneously: a first top glass panel may be loaded into the first fixture, an image display panel may be loaded into the second fixture, the first gripper assembly may connect a second top glass panel to an optical film segment, and the second gripper assembly may grasp a subassembly supported by the dispensing surface. These simultaneous actions may reduce the cycle time for manufacturing an assembly depending on the time required to perform the steps described above. For example, it may be advantageous to remove the subassembly from the liner at the second manufacturing position so that the second gripper assembly is not idle while the first gripper assembly performs several time-consuming tasks.

The apparatus and method described above advantageously provide an invention in which the power required to provide a vacuum is significantly less than in previous devices and methods. This reduced power requirement is achieved due to the small chamber size in which the vacuum is provided. The reduced power requirement also reduces the cost of the image display assembly compared to previous assemblies. This reduced power and smaller volume also reduces the cycle time of producing one part significantly compared to other techniques. Furthermore, the apparatus and method also advantageously result in more precisely assembled components compared to manual assembly methods. As such, fewer image display assemblies are manufactured that require subsequent reworking.

While there has been shown and described what is at present considered the preferred embodiment of the invention, it will be obvious to those skilled in the art that various changes and modifications can be made therein without departing from the scope of the invention defined by the appended claims.

We claim:

1. An image display assembly, comprising:
a top glass panel having peripheral edges;
an optical film engaged with said top glass panel and having peripheral edges, at least a first of said peripheral edges of said optical film being disposed inwardly from an adjacent peripheral edge of said top glass panel; and
an image display panel engaged with said optical film opposite said top glass panel and having peripheral edges, a peripheral edge of said image display panel adjacent said first of said peripheral edges of said optical film being disposed outwardly from said first of said peripheral edges of said optical film to define an undercut between said optical film and said top glass panel and between said optical film and said image display panel.

2. The image display assembly as in claim 1, wherein said undercut extends around a perimeter of said optical film.

3. The image display assembly as in claim 1, wherein said peripheral edges of said top glass panel define a first perimeter length, said peripheral edges of said optical film define a second perimeter length, and said first perimeter length is greater than said second perimeter length.

4. The image display assembly as in claim 3, wherein said peripheral edges of said image display panel define a third perimeter length, and said third perimeter length is greater than said second perimeter length.

5. An apparatus for applying an optical film, comprising:
a support surface;
a vacuum head having an open end sealable against said support surface, said vacuum head being movable between an open position spaced away from said support surface and a sealed position sealingly engaging said support surface; and
a gripper movably mounted in said vacuum head.

6. The apparatus as in claim 5, wherein said support surface is a first support surface, said vacuum head is a first vacuum head, said gripper is a first gripper, and further comprising:
a second support surface;
a second vacuum head having an open end sealable against said second support surface, said second vacuum head being movable between an open position spaced above said second support surface and a sealed position sealingly engaging said second support surface;
a second gripper movably mounted in said second vacuum head; and
an index table having a plurality of support fixtures, said index table being rotatable to move said support fixtures from a first manufacturing position proximate said first vacuum head to a second manufacturing position proximate said second vacuum head.

7. The apparatus of claim 6, further comprising an optical film dispenser having a dispensing platform, said first support surface being an optical film liner supported by said dispensing platform.

8. The apparatus as in claim 7, further comprising an enclosure isolating said first vacuum head, said second vacuum head, and said optical film dispenser from an outside environment.

9. A method of applying an optical film, said method comprising:
positioning said optical film and one of a top glass panel and an image display panel supported by a first gripper hand of a first gripper assembly within a first vacuum head of said first gripper assembly;
forming a seal at an open end of said first vacuum head;
removing air from within said first vacuum head to provide a first vacuum chamber therein, said optical film and said one of a top glass panel and an image display panel being disposed in said first vacuum chamber;
engaging said optical film with said one of a top glass panel and an image display panel by pressing said one of a top glass panel and an image display panel against said optical film within said first vacuum chamber and using said first gripper hand; and
removing a liner releasably supporting said optical film.

10. The method as in claim 9, in which forming said seal at said open end of said first vacuum head includes engaging said open end against said liner.

11. The method as in claim 9, in which removing said liner releasably supporting said optical film includes displacing a dispensing platform supporting said liner.

12. The method of claim 9, in which said one of a top glass panel and an image display panel is a top glass panel and said optical film engaged with said top glass panel defines a subassembly, and further comprising:
positioning an image display panel supported by a fixture and said subassembly supported by a second gripper hand of a second gripper assembly within a second vacuum head of said second gripper assembly;
forming a seal between said second vacuum head and said fixture;
removing air from within said second vacuum head to provide a second vacuum chamber therein, said subassembly and said image display panel being disposed in said second vacuum chamber; and
engaging said subassembly with said image display panel by pressing said optical film against said image display panel using said second gripper hand.

13. The method of claim 12, including removing said top glass panel from said fixture prior to engaging said optical film with said top glass panel, and positioning said subassembly on said fixture after engaging said optical film with said top glass panel.

14. The method of claim 13, including positioning said optical film to define an undercut between said optical film and said top glass panel.

15. The method of claim 9, in which said one of a top glass panel and an image display panel is an image display panel and said optical film engaged with said image display panel defines a subassembly, and further comprising:
positioning a top glass panel supported by a fixture and said subassembly supported by a second gripper hand of a second gripper assembly within a second vacuum head of said second gripper assembly;
forming a seal between said second vacuum head and said fixture;
removing air from within said second vacuum head to provide a second vacuum chamber therein, said subassembly and said top glass panel being disposed in said second vacuum chamber; and
engaging said subassembly with said top glass panel by pressing said optical film against said top glass panel using said second gripper hand.

16. The method of claim 9, including moving said one of a top glass panel or an image display panel along a linear path to deliver said one of a top glass panel or an image display panel to said first gripper assembly.

17. The method of claim 9, including moving said liner releasably supporting said optical film towards a second gripper assembly before removing said liner from said optical film.
